(19) United States
(12) Patent Application Publication
(10) Pub. No.: US 2026/0125588 A1
(43) Pub. Date: May 7, 2026

(54) POLISHING AGENT, POLISHING METHOD, METHOD FOR MANUFACTURING SEMICONDUCTOR COMPONENT, ADDITIVE SOLUTION FOR POLISHING AGENT, AND METHOD FOR MANUFACTURING ADDITIVE SOLUTION FOR POLISHING AGENT

(71) Applicant: AGC Inc., Tokyo (JP)

(72) Inventor: Masatoshi AKAJI, Tokyo (JP)

(73) Assignee: AGC Inc., Tokyo (JP)

(21) Appl. No.: 19/439,607

(22) Filed: Jan. 5, 2026

Related U.S. Application Data
(63) Continuation of application No. PCT/JP2024/022814, filed on Jun. 24, 2024.

(30) Foreign Application Priority Data
Jul. 7, 2023 (JP) 2023-112030

(51) Int. Cl. C09K 3/14; H10P 52/40

(52) U.S. Cl. CPC C09K 3/1463; H10P 52/402

(57) ABSTRACT

A polishing agent with excellent pH stability, an additive solution for a polishing agent for preparing the polishing agent and a method for manufacturing the same, a polishing method capable of performing high-speed polishing, and a method for manufacturing a semiconductor component using the polishing method are provided. A polishing agent contains (bi)carbonate of a primary amine, a secondary amine, a tertiary amine, or a quaternary ammonium, and water, in which an organic group that the amine or the ammonium has is a group selected from a linear alkyl group, a branched alkyl group, and an alkanol group, a content of the (bi)carbonate is 5 mmol/L to 130 mmol/L based on the whole polishing agent, a boiling point of the amine or the ammonium is 0° C. to 500° C., and pH is 7 to 11.

### INCORPORATION BY REFERENCE

This application is based upon and claims the benefit of priority from Japanese patent application No. 2023-112030, filed on Jul. 7, 2023, and PCT application No. PCT/JP2024/022814 filed on Jun. 24, 2024, the disclosure of which is incorporated herein in its entirety by reference.

### BACKGROUND

The present invention relates to a polishing agent, a polishing method, a method for manufacturing a semiconductor component, an additive solution for a polishing agent, and a method for manufacturing an additive solution for a polishing agent.

As packing densities of semiconductor integrated circuits increase and their functions become more sophisticated, the development of microfabrication technology for making structures of semiconductor elements finer and more densified has been progressing. In the manufacturing of semiconductor integrated circuit devices (hereinafter also referred to as semiconductor devices), conventionally, interlayer insulating films, buried wiring lines, and the like are flattened by using Chemical Mechanical Polishing (hereinafter referred to as CMP) in order to prevent a problem that irregularities (differences in level) on the surface of a layer exceed the focal depth of lithography and hence a sufficient resolution cannot be obtained. As the demand for making elements more precise and finer is increasing, the importance of high flatness obtained by CMP is increasing more and more.

Further, in the manufacture of semiconductor devices, shallow trench isolation (STI: Shallow Trench Isolation) in which an element isolation width is small has been introduced in order to make semiconductor devices finer even further.

STI is a method for forming an electrically insulated element region by forming a trench (groove) in a silicon substrate and embedding an insulating film in the trench. An example of STI will be described with reference to FIGS. 1A and 1B. In this example, first, as shown in FIG. 1A, an element region on a silicon substrate 1 is masked with a stopper film 2. Then, a trench 3 is formed in the silicon substrate 1, and an insulating film such as a silicon oxide film 4 is deposited so as to fill the trench 3 therewith. Next, by CMP, while leaving the part of the silicon oxide film 4 located inside the trench 3, which is a recessed part, the remaining part of the silicon oxide film 4 located over the stopper film 2, which is a protruding part(s), is polished and thereby removed. By doing so, an element isolation structure in which the silicon oxide film 4 is embedded in the trench 3 is obtained as shown in FIG. 1B.

As an example of the polishing agent used for CMP, Patent Literature 1 discloses a polishing agent containing cerium oxide particles, water-soluble polyamine, potassium hydroxide, and an organic acid and having pH of 10 or more.
Patent Literature 1: Japanese Unexamined Patent Application Publication No. 2016-154208

### SUMMARY

It is known that the polishing performance of the polishing agent varies depending on pH changes. In order to stabilize the performance of the polishing agent, a polishing agent with excellent pH stability has been required. In particular, an alkaline polishing agent tends to become acidic as it absorbs carbon dioxide gas in the air, which causes a problem that the polishing performance is unlikely to be stable.

In view of the above-described problem, an object of the present disclosure is to provide a polishing agent with excellent pH stability, an additive solution for a polishing agent for preparing the polishing agent and a method for manufacturing the same, a polishing method capable of performing high-speed polishing, and a method for manufacturing a semiconductor component using the polishing method.

The present disclosure provides a polishing agent, a polishing method, a method for manufacturing a semiconductor component, an additive solution for a polishing agent, and a method for manufacturing an additive solution for a polishing agent.
[1] A polishing agent containing:
   abrasive grains; and
   (bi)carbonate of a primary amine, a secondary amine, a tertiary amine, or a quaternary ammonium, and water, wherein
   an organic group that the amine or the ammonium has is a group selected from a linear alkyl group, a branched alkyl group, and an alkanol group, . . . ,
   a content of the (bi)carbonate is 5 mmol/L to 130 mmol/L based on the whole polishing agent,
   a boiling point of the amine or the ammonium is 0° C. to 500° C., and
   pH is 7 to 11.
[2] The polishing agent described in Item [1], wherein a molecular weight of the (bi)carbonate is 500 or less.
[3] The polishing agent described in Item [1] or [2], wherein a melting point of the amine or the ammonium is −180° C. to 0° C.
[4] The polishing agent described in any one of Items [1] to [3], wherein an absolute value of a difference between pka of ammonium ions in the (bi)carbonate and pH of the polishing agent is 3 or less.
[5] The polishing agent described in any one of Items [1] to [4], wherein the organic group includes an alkanol group.
[6] The polishing agent described in any one of Items [1] to [5], wherein the (bi)carbonate includes (bi)carbonate of a tertiary amine.
[7] The polishing agent described in any one of Items [1] to [6], wherein the abrasive grains include at least one type selected from the group consisting of silica particles, alumina particles, zirconia particles, cerium compound particles, titania particles, germania particles, composite particles thereof, and core shell-type particles.
[8] The polishing agent described in any one of Items [1] to [7], wherein the abrasive grains include cerium compound particles.
[9] The polishing agent described in any one of Items [1] to [8], wherein the abrasive grains include ceria particles.
[10] The polishing agent described in any one of Items [1] to [9], wherein a content of the abrasive grains is 0.01 wt. % to 10.0 wt. % based on a total weight of the polishing agent.
[11] A polishing method in which a polishing pad is brought into contact with a surface to be polished of a semiconductor substrate while supplying a polishing agent therebetween, and the surface to be polished is polished by relative motion of the surface to be polished and the polishing pad,
   wherein the polishing agent is the polishing agent described in any one of Items [1] to [10].
[12] A method for manufacturing a semiconductor component, wherein the semiconductor component is obtained by dividing a semiconductor substrate having a surface to be polished, polished by the polishing method according to Item [11] into pieces.
[13] An additive solution for a polishing agent containing (bi)carbonate of a primary amine, a secondary amine, a tertiary amine, or a quaternary ammonium, and water,
   wherein an organic group that the amine or the ammonium has is a group selected from a linear alkyl group, a branched alkyl group, an alkanol group, . . . .
[14] A method for manufacturing the additive solution for the polishing agent described in Item [13], the method comprising:
   dissolving a primary amine, a secondary amine, a tertiary amine, or a quaternary ammonium in water; and
   supplying carbon dioxide gas to the water to generate (bi)carbonate.

According to the present disclosure, it is possible to provide a polishing agent with excellent pH stability, an additive solution for a polishing agent for preparing the polishing agent and a method for manufacturing the same, a polishing method capable of performing high-speed polishing, and a method for manufacturing a semiconductor component using the polishing method.

The above and other objects, features and advantages of the present disclosure will become more fully understood from the detailed description given hereinbelow and the accompanying drawings.

### BRIEF DESCRIPTION OF DRAWINGS

FIG. 1A shows an example of a polishing method, and is a cross-sectional diagram showing a state of an object to be polished before being polished;

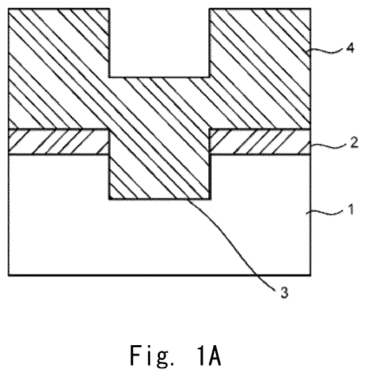

FIG. 1B shows the example of the polishing method, and is a cross-sectional diagram showing a state of the object to be polished after being polished; and

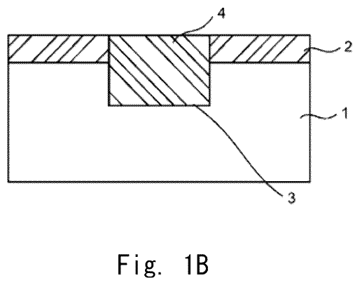

FIG. 2 is a schematic diagram showing an example of a polishing apparatus.

### DESCRIPTION OF EMBODIMENT

Embodiments according to the present invention will be described hereinafter. The present invention is not limited to the below-shown embodiments, and other embodiments may also fall within the scope of the present invention as long as they are consistent with the purport of the present invention. For clarifying the explanation, the following description and drawings are simplified as appropriate. Further, for the sake of explanation, the scales of members in the drawings may widely differ from one another.

Note that in the present invention, the term “surface to be polished” means a surface to be polished of an object to be polished, for example, a front surface thereof. In the specification of the present application, surfaces at intermediate stages, i.e., surfaces that appear in semiconductor substrates during a process for manufacturing a semiconductor device, are also included in the “surface to be polished”.

The term “silicon oxide” is mainly silicon dioxide, but it is not limited to silicon dioxide and may include silicon oxides other than silicon dioxide.

The term “selective ratio” means a ratio (R_{A}/R_{B}) of a removal rate (R_{A}) of an object to be polished A (e.g., a silicon oxide film) to a removal rate (R_{B}) of a stopper film B (e.g., a silicon nitride film). The term “(bi)carbonate” is a general term for carbonates and bicarbonates.

The term “amine” is a general term for primary amines, secondary amines, and tertiary amines. Further, amine and ammonium may be collectively referred to as “amine or the like”.

Further, unless otherwise specified, when a symbol “-” (or “to”), which indicates a numerical range, is used, it means that a numerical value in front of the symbol and that behind the symbol are included as a lower limit value and an upper limit value, respectively, in the range.

### [Polishing Agent]

The polishing agent according to the present invention (hereinafter also referred to as the polishing agent disclosed herein) is a polishing agent containing (bi)carbonate of a primary amine, a secondary amine, a tertiary amine, or a quaternary ammonium, and water, in which an organic group that the amine or the ammonium has is a group selected from a linear alkyl group, a branched alkyl group, and an alkanol group, the content of the (bi)carbonate is 5 mmol/L to 130 mmol/L based on the whole polishing agent, a boiling point of the amine or the ammonium is 0° C. to 500° C., and pH is 7 to 11.

Since the polishing agent disclosed herein contains (bi)carbonate of amine or the like, absorption of carbon dioxide in the atmosphere can be suppressed, and pH changes can be suppressed even when pH is 7 or more. As a result, the polishing performance of the polishing agent becomes stable.

The polishing agent disclosed herein contains at least abrasive grains, (bi)carbonate of amine or the like, and water, and may further contain other components as long as the effect of the present invention is achieved. Hereinafter, each of the components that may be contained in the polishing agent disclosed herein will be described.

### <(Bi)carbonate of Amine or Ammonium>

The polishing agent disclosed herein contains (bi)carbonate of the specific amine or the like described above. Since the above (bi)carbonate is unlikely to absorb carbon dioxide, it has excellent pH stability. Further, amine and ammonium have higher pH stability than ammonia does since they have lower volatility than ammonia does.

(Bi)carbonate may be either a salt of carbonate ions (CO₃²⁻) or a salt of bicarbonate ions (HCO₃⁻). The ratio of the carbonate ions to the bicarbonate ions depends on pH or the like of the polishing agent. Regardless of the ratio, (bi)carbonate exerts an effect on pH stability.

Further, amine or ammonium used in the polishing agent disclosed herein has a group selected from a linear alkyl group, a branched alkyl group, and an alkanol group.

The linear alkyl group is preferably an alkyl group having a carbon number of 1 to 24, and preferably an alkyl group having a carbon number of 1 to 12. Specific examples of the linear alkyl group include a methyl group, an ethyl group, an n-propyl group, an n-butyl group, an n-hexyl group, and an n-octyl group.

The branched alkyl group is preferably an alkyl group having a carbon number of 3 to 24, and more preferably an alkyl group having a carbon number of 3 to 12. Specific examples of the branched alkyl group include an isopropyl group, a sec-butyl group, an isobutyl group, and a tert-butyl group.

Further, examples of the alkanol group include a structure in which one or more hydrogen atoms of the linear alkyl group or the branched alkyl group stated above are substituted by a hydroxyl group. Specific examples of the alkanol group include a hydroxyethyl group and a hydroxypropyl group.

Two or more organic groups in the secondary amine, the tertiary amine, and the quaternary ammonium may be the same group or may be different groups. In the polishing agent disclosed herein, the amine or the like preferably has an alkanol group since the boiling point becomes high (low volatility), solubility increases, and pH becomes more stable.

The boiling point of the amine or the like is 0° C. to 500° C. By using amine or the like whose boiling point is 0° C. or higher, pH stability is improved. In addition, by using amine or the like whose boiling point is 500° C. or lower, distillation and purification of the amine can be performed relatively easily when (bi)carbonates of amine or the like are synthesized.

The lower limit value of the boiling point of the amine or the like is preferably 30° C., more preferably 50° C., and further preferably 70° C. in order to further improve pH stability. The higher the boiling point of amine or the like, the more the pH changes associated with evaporation are suppressed, which causes pH stability to be further improved. On the other hand, the upper limit value of the boiling point of the amine or the like is preferably 400° C., and more preferably 300° C. in view of availability of (bi)carbonate.

The upper limit value of the melting point of the amine or the like is determined in view of manufacturing of the polishing agent. The melting point is preferably low, which is because, when the amine or the like is thermally melted at a time of preparation of the polishing agent, it is possible that the amine or the like may be oxidized due to the presence of oxygen in the atmosphere, and when the amine or the like is (bi)carbonate, the amin or the like may be decomposed due to formation of carbamic acid or urea derivatives. In view of the above points, the upper limit value of the melting point of the amine or the like is preferably 0° C., more preferably −30° C., further preferably −50° C., and particularly preferably −80° C. On the other hand, the lower limit value of the melting point of the amine or the like is preferably −180° C., and more preferably −140° C. in view of handling by solidification.

Specific examples of amine and ammonium include primary amines such as methylamine, ethylamine, propylamine, isopropylamine, butylamine, hexylamine, heptylamine, octylamine, monoethanolamine, isopropanolamine, 2-amino-1-propanol, 3-amino-1-propanol;
secondary amines such as dimethylamine, diethylamine, methylethylamine, dibutylamine, diethanolamine, and diisopropanolamine;
tertiary amines such as trimethylamine, triethylamine, tripropylamine, tributylamine, triethanolamine, triisopropanolamine, ethyl diethanolamine, butyldiethanolamine, and dimethylpropane-1-amine;
quaternary ammoniums such as tetramethylammonium, tetraethyl ammonium, tetrapropylammonium, tetrabutylammonium, ethyltrimethylammonium, diethyldimethylammonium, and methyltriethylammonium.

In order to further improve pH stability, among them, a tertiary amine or a quaternary ammonium is preferable, a tertiary amine is more preferable, and a tertiary amine having an alkanol group is further preferable.

The molecular weight of (bi)carbonate of amine or the like is preferably as low as possible, preferably 50 to 500, and further preferably 50 to 300 so that it is possible to reduce the amount thereof to be added and thus reduce the environmental load.

Further, pKa of ammonium ions in (bi)carbonate of amine or the like is preferably 7 to 12, more preferably 7.5 to 11, and further preferably 8 to 11 in view of pH stability.

Likewise, in view of pH stability, an absolute value |pKa−pH| of a difference between pKa of ammonium ions in (bi)carbonate of amine or the like and pH of the polishing agent disclosed herein is preferably 3 or less, more preferably 2 or less, further preferably 1.5 or less, and particularly preferably 1.0 or less.

The above-described ammonium ions represent conjugate acids of amine or the like, and when pka of the ammonium ions is equal to or higher than the pH of the polishing agent, most of the amine or the like becomes ammonium ions. Specifically, when, for example, the pKa is greater than the value of pH of the polishing agent by 1 or more, appropriately 90% or more of the amine or the like becomes ammonium ions. The amine or the like existing in the form of ammonium ions is less likely to evaporate, and even when, for example, the boiling point of the amine or the like is low, it has excellent pH stability and low volatility, whereby it is possible to prevent adverse effects on other adjacent platens in the CMP apparatus.

The content of (bi)carbonate of amine or the like is preferably 5 mmol/L to 130 mmol/L, and more preferably 10 mmol/L to 80 mmol/L based on the whole polishing agent in order to further improve pH stability.

### (Method for Manufacturing (Bi)Carbonate of Amine or the Like)

(Bi)carbonate of amine or the like may be a commercially available product. Further, (bi)carbonate of amine or the like may be generated by supplying carbon dioxide gas to a desired amine or the like to be used.

Specific examples of a method for manufacturing (bi)carbonate of amine or the like include (I) a method for preparing an aqueous solution of amine or the like and causing this aqueous solution to absorb carbon dioxide gas; (II) a method for mixing dry ice and amine or the like; and (III) a method for mixing ammonium (bi)carbonate and amine or the like, dissociating ammonia through weak base dissociation, and removing the dissociated ammonia.

In the above method (I), carbon dioxide gas may either be high-purity gas or CO₂ in the atmosphere. Further, (bi)carbonate of amine or the like generated by an amine absorption method or the like, which is also known as Direct Air Capture (DAC) of CO₂, may be used.

### <Abrasive Grains>

In the polishing agent disclosed herein, the abrasive grains may be selected as appropriate from among those used as abrasive grains for CMP. Examples of abrasive grains include at least one type selected from the group consisting of silica particles, alumina particles, zirconia particles, cerium compound particles (e.g., ceria particles, cerium hydroxide particles), titania particles, germania particles, and core shell-type particles using these particles as core particles. Examples of the silica particles include colloidal silica and fumed silica. Colloidal alumina may also be used as the alumina particles.

The core shell-type particles consist of core particles (e.g., silica particles, alumina particles, zirconia particles, cerium compound particles, titania particles, or germania particles) and thin films covering the surfaces of the core particles.

Examples of the material of the thin film include at least one type selected from oxides such as silica, alumina, zirconia, ceria, titania, germania, iron oxide, manganese oxide, zinc oxide, yttrium oxide, calcium oxide, magnesium oxide, lanthanum oxide, and strontium oxide. Further, the thin film may be formed from a plurality of nanoparticles consisting of these oxides.

The particle size of the aforementioned core particles is preferably 0.01 μm to 0.5 μm and more preferably 0.03 μm to 0.3 μm.

It is sufficient if the particle size of the aforementioned nanoparticles is smaller than the particle size of the aforementioned core particles, and the particle size of the nanoparticles preferably 1 nm to 100 nm and more preferably 5 nm to 80 nm.

Among the above-mentioned abrasive grains, silica particles, alumina particles, or cerium compound particles are preferred in view of the excellent removal rate of the insulating film. Further, cerium compound particles are more preferred, and ceria particles are still more preferred because a high removal rate can be obtained when the surface to be polished includes an insulating film (in particular, a silicon oxide film). In the case of core shell-type particles, the thin film preferably contains silica, alumina, or a cerium compound. More preferably, the thin film contains ceria. Only one type of abrasive grains may be used, or two or more types of abrasive grains may be used in combination.

The content of ceria based on the total weight of abrasive grains is preferably 70 wt. % or more, more preferably 80 wt. % or more, still more preferably 90 wt. % or more, particularly preferably 95 wt. % or more, and most preferably 100 wt. %. When the content of ceria based on the total weight of abrasive grains is 70 wt. % or more, it is easy to improve, in particular, the removal rate of the insulating film.

Ceria particles may be selected as appropriate from known ones and used. Examples of known ceria particles include ceria particles manufactured by methods disclosed in Japanese Unexamined Patent Application Publication No. H11-12561, Japanese Unexamined Patent Application Publication No. 2001-35818, and Published Japanese Translation of PCT International Publication for Patent Application, No. 2010-505735. Specifically, examples of them include ceria particles obtained by manufacturing cerium hydroxide gel by adding an alkali to an aqueous solution of cerium (IV) ammonia nitrate, and then filtering, washing, and firing the manufactured gel; the ceria particles obtained by pulverizing and then firing highly-pure cerium carbonate, and further pulverizing and classifying the pulverized and fired cerium carbonate; and ceria particles obtained by chemically oxidizing a cerium (III) salt in a liquid.

The ceria particles may contain impurities other than ceria. However, the content of ceria in one ceria particle is preferably 80 wt. % or more, more preferably 90 wt. % or more, further preferably 95% or more, and most preferably 100 wt. % (containing no impurities). When the content of ceria in the ceria particles is 80 wt. % or more, it is easy to improve the removal rate of the insulating film.

The average particle size of the abrasive grains is preferably 0.01 μm to 0.5 μm and more preferably 0.03 μm to 0.3 μm. When the average particle size is 0.5 μm or shorter, the mechanical effect on the surface to be polished is reduced, so that the occurrence of polishing damage such as scratches on the surface to be polished is suppressed. Further, when the average particle size is 0.01 μm or longer, the aggregation of abrasive grains is suppressed, so that the storage stability of the polishing agent is excellent and the removal rate is also excellent.

Note that, when the abrasive grains are dispersed and not aggregated in the liquid, the above-described particle size is the particle size of primary particles. When the abrasive grains are aggregated in the liquid, the above particle size is a particle size of the aggregated particles (secondary particles). In either case, the average particle size is measured by using a dispersion liquid in which abrasive grains are dispersed in a dispersion medium such as pure water and using a particle-size distribution meter such as a laser diffraction/scattering type meter.

The lower limit value of the content of abrasive grains is preferably 0.01 wt. %, more preferably 0.05 wt. %, still more preferably 0.1 wt. %, and particularly preferably 0.15 wt. % based on the total weight of the polishing agent. When the content of abrasive grains is equal to or higher than the aforementioned lower limit value, an excellent removal rate for the surface to be polished can be obtained. On the other hand, the upper limit value of the content of abrasive grains is preferably 10.0 wt. %, more preferably 8.0 wt. %, still more preferably 5.0 wt. %, particularly preferably 2.0 wt. %, still particularly preferably 1.0 wt. %, extremely preferably 0.8 wt. %, and most preferably 0.5 wt. % based on the total weight of the polishing agent. When the content of abrasive grains is equal to or lower than the upper limit value, the agglomeration of abrasive grains can be suppressed; the increase in the viscosity of the polishing agent disclosed herein can be suppressed; and the handling property is excellent.

The zeta potential (surface potential) of the abrasive grains in the polishing agent is preferably negative (lower than 0 mV), more preferably −200 mV to −10 mV, still more preferably −150 mV to −20 mV, and particularly preferably −100 mV to −30 mV. When the zeta potential of the abrasive grains is within the above-described range, the dispersion stability of the abrasive grains and the flatness of the silicon oxide film after the polishing can be improved.

The zeta potential of the abrasive grains can be measured by using, for example, a dynamic light scattering-type zeta potential measuring apparatus (e.g., Product Name: DelsaNano C manufactured by Beckman Coulter Co., Ltd.). The zeta potential of the abrasive grains can be adjusted by using a water-soluble polymer, an acidic compound, an additive, or the like (which will be described later).

### <Water>

The polishing agent disclosed herein contains water as a medium in which abrasive grains are dispersed. The type of water is not limited to any particular types. However, it is preferred to use pure water, ultrapure water, ion exchange water, or the like in consideration of the effects on other components, the prevention of the contamination by impurities, and the effects on pH and the like.

### <Additive>

The polishing agent disclosed herein may also contain various additives. Examples of additives include a pH adjusting agent, a dispersant, an agglomeration inhibitor, a lubricant, a viscosity imparting agent, a viscosity adjusting agent, and a preservative. Further, the polishing agent may contain two or more types of additives. While (bi)carbonate of amine or the like described above may be contained in the pH adjusting agent as well, (bi)carbonate of amine or the like is treated separately from the pH adjusting agent in the polishing agent disclosed herein.

### (pH Adjusting Agent)

A pH adjusting agent may be contained in order to adjust pH to a predetermined value. The pH adjusting agent may be selected as appropriate from acidic compounds, basic compounds, amphoteric compounds such as amino acids, and salts thereof.

Examples of the acidic compounds include inorganic acids, organic acids, or salts thereof. Examples of the inorganic acids include nitric acid, sulfuric acid, hydrochloric acid, and phosphoric acid. Further, their ammonium salts, sodium salts, potassium salts, or the like may be used.

Examples of the organic acids include compounds having a carboxy group, a sulfo group, or a phospho group as an anionic group, and their ammonium salts, sodium salts, potassium salts or the like.

Examples of the organic acid having a carboxy group include alkyl monocarboxylic acids such as formic acid, acetic acid, and propionic acid;
carboxylic acids having a heterocycle such as 2-pyridinecarboxylic acid, 3-pyridinecarboxylic acid, 4-pyridinecarboxylic acid, 2,3-pyridinedicarboxylic acid, 2,4-pyridinedicarboxylic acid, 2,5-pyridinedicarboxylic acid, 2,6-pyridinedicarboxylic acid, 3,4-pyridinedicarboxylic acid, 3,5-pyridinedicarboxylic acid, pyrazinecarboxylic acid, 2,3-pyrazinedicarboxylic acid, 2-quinolinecarboxylic acid, pyroglutamic acid, picolinic acid, DL-pipecolic acid, 2-furancarboxylic acid, 3-furancarboxylic acid, tetrahydrofuran-2-carboxylic acid, and tetrahydrofuran-2, 3, 4, 5-tetracarboxylic acid;
alicyclic carboxylic acids such as cyclopentanecarboxylic acid, cyclohexanecarboxylic acid, cycloheptanecarboxylic acid, and cyclohexylcarboxylic acid;
carboxylic acids containing an amino group such as alanine, glycine, glycylglycine, aminobutyric acid, N-acetylglycine, N,N-di(2-hydroxyethyl)glycine, N-(tert-butoxycarbonyl)glycine, proline, trans-4-hydroxy-L-proline, phenylalanine, sarcosine, hydantoic acid, creatine, N-[tris(hydroxymethyl)methyl]glycine, glutamic acid, and aspartic acid;
carboxylic acids containing a hydroxyl group such as lactic acid, malic acid, citric acid, tartaric acid, glycolic acid, gluconic acid, salicylic acid, 2-hydroxyisobutyric acid, glyceric acid, 2,2-bis(hydroxymethyl)propionic acid, and 2,2-bis(hydroxymethyl)butyric acid;
carboxylic acids having a ketone group (keto acids) such as pyruvic acid, acetoacetic acid, and levulinic acid; and
dicarboxylic acids such as oxalic acid, malonic acid, succinic acid, fumaric acid, maleic acid, glutaric acid, adipic acid, and phthalic acid.

When an acid is used as the pH adjusting agent in the polishing agent disclosed herein, inorganic acids are preferable, and among them, nitric acid, sulfuric acid, hydrochloric acid, phosphoric acid, and their ammonium salts, sodium salts, and potassium salts are preferred.

Examples of basic compounds include sodium hydroxide, potassium hydroxide, ammonium hydroxide, potassium carbonate, sodium carbonate, and ammonium carbonate; and quaternary ammonium hydroxides such as tetramethylammonium hydroxide, and tetraethylammonium hydroxide.

Further, examples of amphoteric compounds include glycine, alanine, and phenylalanine.

Only one type of pH adjusting agent may be used, or two or more types may be used in combination. In order to suppress aggregation of abrasive grains and further improve the selective ratio, pH of the polishing agent disclosed herein is preferably 7 to 11, more preferably 8 to 10.5, and further preferably 8.5 to 10. The pH adjusting agent may be adjusted as appropriate in order to achieve the above pH. As one example, the pH adjusting agent may be 0.005 wt. % to 2.0 wt. %, preferably 0.01 wt. % to 1.5 wt. %, and more preferably 0.01 wt. % to 0.3 wt. % based on the whole polishing agent disclosed herein.

### (Dispersant)

The polishing agent disclosed herein may contain a dispersant in order to improve the dispersibility of abrasive grains. Examples of dispersants include anionic surfactants, cationic surfactants, nonionic surfactants, and amphoteric surfactants. Only one type of dispersant may be used, or two or more types of dispersants may be used.

The anionic surfactant is preferably a polymer having a carboxy group, an ammonium carboxylate, or the like, and more preferably polyacrylic acid or polyacrylate.

Examples of cationic surfactants include a diallyldimethylammonium chloride polymer, a diallyldimethylammonium chloride/sulfur dioxide copolymer, a diallyldimethylammonium chloride/acrylamide copolymer, a diallyldimethylammonium chloride/maleic acid copolymer, and a maleic acid/diallyldimethylammonium ethyl sulfate/sulfur dioxide copolymer.

The weight-average molecular weight of the above-described surfactant is preferably 10,000 to 100,000 in order to polish the surface to be polished at a higher speed.

When a dispersant is used, its content is preferably 0.0001 wt. % to 0.3 wt. %, more preferably 0.001 wt. % to 0.2 wt. %, and still more preferably 0.01 wt. % to 0.15 wt. % based on the total weight of the polishing agent in order to polish the surface to be polished at a higher speed.

When the above-described additives are used in the polishing agent disclosed herein, the total content of the additives is preferably 0.01 to 10.0 wt. % and still more preferably 0.01 to 5.0 wt. % based on the total weight of the polishing agent.

The method for preparing the polishing agent disclosed herein may be selected as appropriate from among methods in which abrasive grains, (bi)carbonate of amine or the like, and each of components that are used as required are uniformly dispersed or dissolved in water, which is the medium.

For example, the polishing agent disclosed herein may be prepared by separately preparing a dispersion liquid of abrasive grains and an additive solution for a polishing agent (which will be described later), and mixing them. According to this method, the storage stability of the above-described dispersion liquid and the additive solution for a polishing agent is improved and the transportation of them becomes easier.

Further, (bi)carbonate of amine or the like may be added in a state of (bi)carbonate, or may be obtained by supplying carbon dioxide gas to a solution after amine or ammonium halide salt is added.

### [Additive Solution for Polishing Agent]

The additive solution for the polishing agent according to this embodiment is an additive solution for preparing a polishing agent by mixing it with a dispersion liquid of abrasive grains as described above. The additive solution for the polishing agent contains (bi)carbonate of a primary amine, a secondary amine, a tertiary amine, or a quaternary ammonium, and water, and may further contain, as necessary, the additive described with regard to the above polishing agent. Note that each of these components is as described above, and therefore descriptions thereof are omitted here.

Note that when a polishing agent is prepared by separately preparing two liquids, i.e., a liquid in which abrasive grains are dispersed and an additive solution for a polishing agent, and then mixing them with each other, it is possible to prepare a liquid in which abrasive grains are dispersed at a concentration 2 to 100 times higher than a predetermined concentration and an additive solution for a polishing agent in which the concentration of the (bi)carbonate is 2 to 100 times higher than a predetermined concentration, and then dilute them to the predetermined concentrations when the polishing agent is used. More specifically, for example, when the concentration of abrasive grains in the dispersion liquid and the concentrations of the (bi)carbonate and the acidic compound in the additive solution are both 10 times their respective predetermined concentrations, a polishing agent is obtained by mixing 10 pts. mass of the dispersion liquid, 10 pts.mass of the additive solution for a polishing agent, and 80 pts.mass of water with each other, and stirring the mixture.

By adding the above-described additive solution for polishing to the dispersion liquid of the abrasive grains, it is possible to obtain a polishing agent with high pH stability and stable abrasive performance.

In the above-described additive solution for polishing, the content ratio (concentration) of (bi)carbonate is preferably 0.001 to 30 wt. %, more preferably 0.01 to 20 wt. %, and still more preferably 0.1 to 10 wt. % based on the whole additive solution.

Further, in the above-described dispersion liquid of abrasive grains, the content ratio of the abrasive grains is preferably 0.2 to 40 wt. %, more preferably 1 to 20 wt. %, and still more preferably 5 to 10 wt. %.

### [Polishing Method]

The polishing method according to the present disclosure is a method for polishing a surface to be polished containing silicon oxide of a semiconductor substrate by bringing a polishing pad into contact with the surface to be polished while supplying a polishing agent therebetween, and polishing the surface to be polished by relative motion of the surface to be polished and the polishing pad.

Note that examples of the surface to be polished include a surface made of silicon dioxide of a semiconductor substrate, a blanket wafer in which a stopper film and a silicon oxide film are laminated on a surface of a semiconductor substrate, and a patterned wafer in which these films are arranged in a pattern. Preferred examples of semiconductor substrates include a substrate for STI. The polishing agent according to the present disclosure is also effective for polishing for flattening an interlayer insulating film between multilayer wiring lines in the manufacture of semiconductor devices.

Note that examples of materials for the stopper film include: compounds containing one or more types selected from silicon, carbon, hafnium, zirconium, cobalt, ruthenium, molybdenum, titanium, tantalum, and copper; and nitrides containing one or more of them, and oxides containing one or more of them. More specifically, examples include: a metal itself such as copper, cobalt, ruthenium, molybdenum, titanium, and tantalum; a nitride such as titanium nitride, tantalum nitride, and silicon nitride; an oxide such as zirconia and hafnium oxide; polysilicon, amorphous silicon, hafnium silicate, zirconium silicate, silicon carbide, and the like. Among them, silicon nitride or polysilicon is preferred in order to obtain a higher selective ratio.

Examples of silicon oxide films in substrates for STI include so-called a PE-TEOS film formed by a plasma CVD method by using tetraethoxysilane (TEOS) as a raw material. Further, examples of silicon oxide films include so-called an HDP film formed by a high-density plasma CVD method. Further, HARP films and FCVD films formed by other CVD methods, and SOD films formed by spin coating can also be used. Examples of silicon nitride films include those formed by a low-pressure CVD method or a plasma CVD method by using silane or dichlorosilane and ammonia as raw materials, and those formed by an ALD method. Further, examples of polysilicon films are those that are formed by a low-pressure CVD method or a plasma CVD method by using silane as a raw material, and then converted into polycrystalline grains by performing a heat treatment.

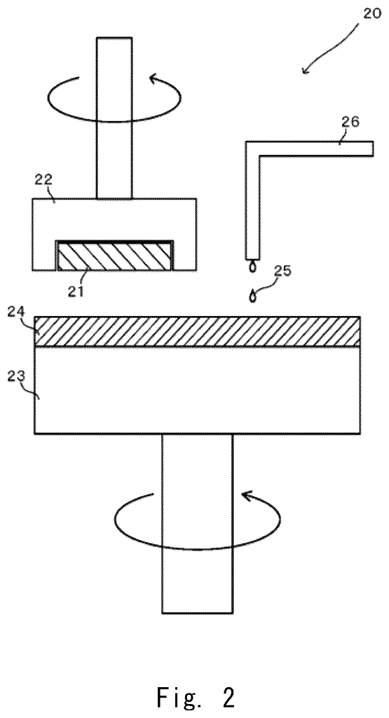

A known polishing apparatus can be used for the polishing method according to the present disclosure. FIG. 2 is a schematic diagram showing an example of a polishing apparatus. A polishing apparatus 20 shown in the example shown in FIG. 2 includes a polishing head 22 that holds a semiconductor substrate 21 such as an STI substrate, a polishing table 23, a polishing pad 24 bonded to the surface of the polishing table 23, and a polishing agent supply pipe 26 through which a polishing agent 25 is supplied to the polishing pad 24. The polishing apparatus 20 is configured so as to polish the surface to be polished of the semiconductor substrate 21 held by the polishing head 22 by bringing the surface to be polished into contact with the polishing pad 24 while supplying the polishing agent 25 through the polishing agent supply pipe 26, and rotationally moving the polishing head 22 and the polishing table 23 relative to each other.

The polishing head 22 may perform not only the rotational movement but also a linear movement. Further, the polishing table 23 and the polishing pad 24 may have sizes roughly equal to or smaller than that of the semiconductor substrate 21. In this case, it is preferred that the polishing head 22 and the polishing table 23 are moved relative to each other, so that the entire surface to be polished of the semiconductor substrate 21 can be polished. Further, the polishing table 23 and the polishing pad 24 do not necessarily have to be those that perform rotational movements. That is, each of them may instead be, for example, moved in one direction by a belt or the like.

Although the polishing conditions of the polishing apparatus 20 are not limited to any particular conditions, it is possible to improve the removal rate by applying a load to the polishing head 22 and thereby pressing the polishing head 22 against the polishing pad 24, and thereby increasing the polishing pressure applied thereto. The polishing pressure is preferably about 0.5 kPa to 50 kPa, and still more preferably about 3 kPa to 40 kPa in view of the uniformity and flatness on the surface to be polished of the semiconductor substrate 21 at the removal rate, and to prevent polishing defects such as scratches. The rotation speeds of the polishing table 23 and the polishing head 22 are preferably about 50 rpm to 500 rpm. Further, the amount of the polishing agent 25 to be supplied is adjusted as appropriate according to the composition of the polishing agent, the above-described polishing conditions, and the like.

As the polishing pad 24, one made of a nonwoven fabric, a foamed polyurethane, a porous resin, a nonporous resin, or the like can be used. In order to increase the supply of the polishing agent 25 to the polishing pad 24 or to make a certain amount of the polishing agent 25 remain in the polishing pad 24, grooves in a lattice pattern, a concentric circular pattern, a spiral pattern, or the like may be formed in the surface of the polishing pad 24 by machining or the like. Further, if necessary, a pad conditioner may be brought into contact with the surface of the polishing pad 24, so that the surface to be polished is polished while the surface of the polishing pad 24 is constantly conditioned.

According to the polishing method in accordance with the present disclosure, it is possible to obtain a high selective ratio between the silicon oxide film and the stopper film while suppressing polishing damage, and to carry out polishing with high flatness.

### [Method of Manufacturing Semiconductor Component]

The method for manufacturing a semiconductor component according to this embodiment is one in which a semiconductor component is obtained by dividing a semiconductor substrate having a surface to polished, polished by the polishing method according to the present invention into pieces.

The method for manufacturing a semiconductor component according to the present disclosure includes at least a dividing step of dividing a semiconductor substrate having a surface to polished, polished by the above-described polishing method into pieces. The dividing step includes, for example, a step of obtaining a semiconductor component, which is a semiconductor chip, by dicing the semiconductor substrate (e.g., a semiconductor wafer) by a known method such as blade dicing, laser dicing, or plasma dicing.

The method for manufacturing a semiconductor component may further include a joining step of joining another member on the surface to be polished of the semiconductor chip. By this step, a semiconductor component, which is an assembly, is obtained.

Examples of other members include a second semiconductor chip and a re-wiring layer. Note that the second semiconductor chip may be a semiconductor chip obtained by the manufacturing method according to the present disclosure, or a semiconductor chip obtained by other methods. The joining step may be, for example, a step in which another member is directly disposed on the surface to be polished and directly joined by fusion bonding, surface activation bonding, or the like, or a step in which the surface to be polished and another member are joined with an adhesive layer therebetween. Examples of the adhesive layer include a metal layer such as a solder layer and a copper layer, a glass layer, and a resin layer such as a polyimide layer and an epoxy layer.

The present disclosure can also provide an electronic device including at least one semiconductor component having a surface to be polished, polished by the polishing method according to the present disclosure.

### EXAMPLES

The present invention will be described hereinafter in a more detailed manner with reference to examples and comparative examples, but the present invention is not limited to these examples. Examples 1 to 5 are examples according to the present disclosure, and Examples 6 to 9 are comparative examples.

### [Measuring Method]

<pH>

The pH was measured at a temperature of 25±5° C. by using a pH meter HM-30R manufactured by DKK-TOA Corporation.

### <Average Secondary Particle Size>

The average secondary particle size was measured by using a laser scattering/diffraction type particle-size distribution measurement apparatus (manufactured by HORIBA, Ltd., apparatus name: LA-950).

### [Polishing Agent]

### <Abrasive Grains>

Ceria particles having a particle size of 80 nm were used as abrasive grains. The content ratio of ceria in the ceria particles was 95 wt. % or higher.

### <(Bi)carbonate>

An aqueous solution of triethylamine, an aqueous solution of N-ethyl diethanolamine, and an aqueous solution of N, N-dimethylpropane-1-amine were prepared and carbon dioxide gas was bubbled through each of these aqueous solutions for 30 to 60 minutes to obtain a (bi)carbonate aqueous solution of each amine.

### <Preparation of Polishing Agent>

A specified amount of polyacrylic acid was added to ultrapure water, the liquid was stirred by using a stirring device and a magnetic stirrer until the liquid became transparent, and thus polyacrylic acid was sufficiently dissolved. Next, a pH adjusting agent was added until a desired pH was attained, and the liquid was sufficiently stirred until the pH value became stable. Then, a specified amount of ceria dispersion liquid was added and stirred and a specified amount of the above (bi)carbonate aqueous solution was added and stirred, thereby obtaining polishing agents (slurry) having the compositions and pH shown in Examples 1 to 8 in Table 1. Further, by mixing the abrasive grains and water, adding the pH adjusting agent, and adjusting pH to that shown in Table 1, the polishing agent shown in Example 9 was obtained. In Table 1, MEA represents monoethanolamine.

### [Evaluation]

### <Evaluation of pH Stability>

First, pH of each of the polishing agents of Examples 1 to 9 immediately after the preparation was measured. After that, 500 g of each of the polishing agents was transferred to a 500 ml wide mouth bottle named Eye Boy (manufactured by AS ONE Corporation), and the bottle was left open to the air for two weeks. The pH of the slurry exposed to the air for two weeks was measured, and pH stability was checked based on the magnitude of ΔpH, which is a difference between pH of the slurry immediately after the preparation and pH of the slurry exposed to the air. The smaller the ΔpH is, the higher the pH stability. Table 1 shows the results.

### <Odor Evaluation>

The strength of the odor was checked by a sensory testing method that uses the sense of smell. Table 1 shows the results.

TABLE 1

| | | | Example 1 | Example 2 | Example 3 | Example 4 | Examle 5 |
|---|---|---|---|---|---|---|---|
| Conditions | Abrasive grain | Type | Celia | Celia | Cella | Celia | Celia |
| | | Particle size (nm) | 80 | 80 | 80 | 80 | 80 |
| | | Content (mass %) | 0.25 | 0.35 | 0.25 | 0.25 | 0.25 |
| | (Bi)carbonate | Type | triethylamine | triethylamine | triethylamine | N- | N.N- |
| | | | carbonate | carbonate | carbonate | ethyldiethanolamine | dimethylpropane- |
| | | | | | | carbonate | 1-aminecarbonate |
| | | Molecular weight | 163.21 | 163.21 | 163.21 | 195.22 | 149.2 |
| | | of carbonate | | | | | |
| | | Boiling point (as | 89.7 | 89.7 | 89.7 | 249 | 66 |
| | | amine) (° C) | | | | | |
| | | Melting point (as | −114.7 | −114.7 | −114.7 | −50 | −115.88 |
| | | amine) (° C) | | | | | |
| | | Solubility (as | 112.4 | 112.4 | 112.4 | ∞ | ∞ |
| | | amine) (g/L) | | | | | |
| | | pKa (of conjugate | 10.75 | 10.75 | 10.75 | 8.6 | 9.83 |
| | | acid) | | | | | |
| | | Concentration (mmol/L) | 12.3 | 36.8 | 61.3 | 50.6 | 50.6 |
| | | Content (mass %) | 0.20 | 0.60 | 1.00 | 0.99 | 0.75 |
| | pH | Type | MEA | MEA | MEA | N- | N.N- |
| | adjusting | | | | | ethyldiethanolamine | dimethylpropane- |
| | agent | | | | | | 1-amine |

| | | | | | | |
|---|---|---|---|---|---|---|
| | pH | 9.30 | 9.40 | 9.30 | 9.30 | 9.30 |
| Results | Δ pH | 0.28 | 0.25 | 0.20 | 0.10 | 0.18 |
| | Odor | no | no | no | no | no |

| | | | Example 6 | Example 7 | Example 8 | Example 9 |
|---|---|---|---|---|---|---|
| Conditions | Abrasive grain | Type | Celia | Celia | Celia | Celia |
| | | Particle size (nm) | 80 | 80 | 80 | 80 |
| | | Content (mass %) | 0.25 | 0.25 | 0.25 | 0.25 |
| | (Bi)carbonate | Type | ammonium | ammonium | ammonium | |
| | | | hydrogen | hydrogen | hydrogen | no |
| | | | carbonate | carbonate | carbonate | |
| | | Molecular weight of carbonate | 79.056 | 79.056 | 79.056 | — |
| | | Boiling point (as amine) (° C.) | −33.34 | −33.34 | −33.34 | — |
| | | Melting point (as amine) (° C.) | −77.73 | −77.73 | −77.73 | — |
| | | Solubility (as amine) (g/L) | 899 | 899 | 899 | — |
| | | pKa (of conjugate acid) | 9.25 | 9.25 | 9.25 | — |
| | | Concentration (mmol/L) | 41.7 | 12.6 | 50.6 | — |
| | pH adjusting agent | Type | MEA | MEA | MEA | MEA |

| | | | | | |
|---|---|---|---|---|---|
| | pH | 9.50 | 9.00 | 9.00 | 9.50 |
| Results | Δ pH | 0.33 | 0.23 | 0.01 | 1.30 |
| | Odor | yes | yes | yes | no |

As shown in Table 1, it has been confirmed that the polishing agents of Examples 1 to 5 containing (bi)carbonate of a specific amine or the like have excellent stability in a pH range of 7 to 11, the odor is suppressed, and thus volatility of ammonia is suppressed. By using the polishing agent disclosed herein in which volatility of ammonia is suppressed, contamination, corrosion, and the like of the polishing apparatus can be suppressed. In carbonates of Examples 6 to 8 that use ammonium hydrogen carbonate, which is (bi)carbonate of ammonium ions (NH4⁺), an odor was generated and volatility of ammonia was confirmed.

### [Polishing Test]

Next, a polishing test was conducted for the polishing agent in Example 2.

### <Polishing Test Method>

The performance of the polishing agent was evaluated by using a fully automatic CMP apparatus FREX300X (manufactured by EBARA CORPORATION). A polyurethane pad (IC-1000 manufactured by DuPont) was used as the polishing pad, and a diamond pad conditioner (manufactured by 3M, product name: A165) was used for the conditioning of the polishing pad. Regarding the polishing conditions, the polishing pressure was 2 Psi; the rotation speed of the polishing table was 80 rpm; and the rotation speed of the polishing head was 81 rpm. Further, the supplying rate of the polishing agent was 250 ml/min.

Each of the following objects was used as the polishing target object (object to be polished).
Silicon oxide film: a blanket wafer with a silicon dioxide film formed by a plasma CVD method by using tetraethoxysilane (TEOS) as a raw material on a 12-inch silicon substrate
Polysilicon film: a blanket wafer with a polysilicon film obtained by performing thermal treatment under 600° C. on a film formed by a low-pressure CVD method by using silane as a raw material on a 12-inch silicon substrate
Silicon nitride film: a blanket wafer with a silicon nitride film formed by a low-pressure CVD method by using silane and ammonia as raw materials on a 12-inch silicon substrate

### <Evaluation Method>

A film thickness meter VM-3210 manufactured by SCREEN Holdings Co., Ltd. was used for the measurement of the thickness of each film. For each blanket wafer, each removal rate was calculated by obtaining a difference between the film thickness before being polished and the film thickness after being polished for one minute. An average value (Å/min) of removal rates obtained from removal rates at 49 points on the surface of the substrate was defined as the removal rate.

The following are the results of the above polishing test.
silicon oxide film removal rate: 1,300 Å/min
polysilicon removal rate: 2,800 Å/min
silicon oxide film removal rate: 300 Å/min

The above results show that the polishing agent disclosed herein has an excellent polishing performance of an oxide film and polysilicon and a high selective ratio between an oxide film and a nitride film. Further, the polishing agent disclosed herein can also be suitably used to polish precious metals such as Ru, Mo, and Co, and metals including Cu and the like.

According to the present invention, for example, high-speed polishing can be carried out in CMP of a surface to be polished including an insulating film. Therefore, a polishing method according to the present disclosure is suitable for the polishing of an insulating film for STI in the manufacturing of semiconductor devices.

From the disclosure thus described, it will be obvious that the embodiments of the disclosure may be varied in many ways. Such variations are not to be regarded as a departure from the spirit and scope of the disclosure, and all such modifications as would be obvious to one skilled in the art are intended for inclusion within the scope of the following claims.

What is claimed is:

1. A polishing agent containing:
abrasive grains; and
(bi)carbonate of a primary amine, a secondary amine, a tertiary amine, or a quaternary ammonium, and water, wherein
an organic group that the amine or the ammonium has is a group selected from a linear alkyl group, a branched alkyl group, and an alkanol group,
a content of the (bi)carbonate is 5 mmol/L to 130 mmol/L based on the whole polishing agent,
a boiling point of the amine or the ammonium is 0° C. to 500° C., and
pH is 7 to 11.

2. The polishing agent according to claim 1, wherein a molecular weight of the (bi)carbonate is 500 or less.

3. The polishing agent according to claim 1, wherein a melting point of the amine or the ammonium is −180° C. to 0° C.

4. The polishing agent according to claim 1, wherein an absolute value of a difference between pKa of ammonium ions in the (bi)carbonate and pH of the polishing agent is 3 or less.

5. The polishing agent according to claim 1, wherein the organic group includes an alkanol group.

6. The polishing agent according to claim 1, wherein the (bi)carbonate includes (bi)carbonate of a tertiary amine.

7. The polishing agent according to claim 1, wherein the abrasive grains include at least one type selected from the group consisting of silica particles, alumina particles, zirconia particles, cerium compound particles, titania particles, germania particles, composite particles thereof, and core shell-type particles.

8. The polishing agent according to claim 2, wherein the abrasive grains include cerium compound particles.

9. The polishing agent according to claim 2, wherein the abrasive grains include ceria particles.

10. The polishing agent according to claim 1, wherein a content of the abrasive grains is 0.01 wt. % to 10.0 wt. % based on a total weight of the polishing agent.

11. A polishing method in which a polishing pad is brought into contact with a surface to be polished of a semiconductor substrate while supplying a polishing agent therebetween, and the surface to be polished is polished by relative motion of the surface to be polished and the polishing pad,
wherein the polishing agent is the polishing agent according to claim 1.

12. A method for manufacturing a semiconductor component, wherein the semiconductor component is obtained by dividing a semiconductor substrate having a surface to be polished, polished by the polishing method according to claim 11 into pieces.

13. An additive solution for a polishing agent containing (bi)carbonate of a primary amine, a secondary amine, a tertiary amine, or a quaternary ammonium, and water,
wherein an organic group that the amine or the ammonium has is a group selected from a linear alkyl group, a branched alkyl group, and an alkanol group.

14. A method for manufacturing the additive solution for the polishing agent according to claim 13, the method comprising:
dissolving a primary amine, a secondary amine, a tertiary amine, or a quaternary ammonium salt in water; and
supplying carbon dioxide gas to the water to generate (bi)carbonate.
